(19) United States
(12) Patent Application Publication
(10) Pub. No.: US 2006/0284660 A1
(43) Pub. Date: Dec. 21, 2006

(54) RESET DEVICE AND DISPLAY DEVICE HAVING SAME

(76) Inventors: Kuan-Hong Hsieh, Shenzhen (CN); Han-Che Wang, Shenzhen (CN); Shin-Hong Chung, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/308,789

(22) Filed: May 4, 2006

(30) Foreign Application Priority Data
Jun. 17, 2005 (CN) 200510035420.4

(51) Int. Cl. H03K 3/02

(52) U.S. Cl. 327/198

(57) ABSTRACT

A reset device includes a reset switch (20) and a reset circuit (30). The reset switch is used for producing a reset command. The reset circuit is used for producing a reset signal to reset a processor (40) in accordance with the reset command. The reset switch includes a delay circuit (301) and a switching circuit (302). The delay circuit delays an input of the reset command to the switching circuit, and the switching circuit produces the reset signal in accordance with the reset command. An electronic device including the processor and the reset device is also provided.

### TECHNICAL FIELD

The present invention relates to a reset device, and particularly to a reset device which can reset a processor of an electronic device.

### RELATED ART

When an electronic device, such as a display device is not working properly, a typical method of re-enabling the electronic device is to discontinue the power supply to the electronic device over a period of time. When the power is re-supplied, a processor of the electronic device is reset by a power-on reset circuit during a boot-up sequence of the electronic device. Therefore, the electronic device recovers to a good working state for use.

Referring to FIG. 4, a schematic block diagram is shown for illustrating power-on resetting of a micro controller unit (simplified as MCU) of an electronic device. A power-on reset circuit 50 includes a power input port (Pin) 500 that receives power from a power supply unit 60. The power supply unit 60 includes a power output port (Pout) 600 that outputs power to both the power input port 500 of the power-on reset circuit 50, and a power input port (Pin) 410 of a MCU 40. The MCU 40 includes a reset port (RST) 400. The reset port 400 is connected to a reset signal output port (Out) 510 of the power-on reset circuit 50. The power-on reset circuit 50 produces a reset signal during the booting-up process of an electronic device incorporating the MCU 40. The reset signal is transmitted to the MCU 40 and resets the MCU 40 via the reset signal output port 510 and the reset port 400, and to ensure that the MCU 40 is in good working order after the boot-up sequence.

The act of discontinuing the power supply (or holding down the power on switch) over a period of time is an unduly time-consuming process for a user to re-enable the MCU 40 by use of the power-on reset circuit 50. Furthermore a non-working electronic device may cause a user to be uneasy and anxious and as a result the user may hit on the power switch continuously, thus, disallowing a proper reboot sequence of the electronic device.

Therefore, there is a need for providing a reset device which can solve the problem described above and provide convenience to users.

### SUMMARY

A reset device for resetting a processor of an electronic device is provided in accordance with a preferred embodiment. The reset device mainly includes a reset switch and a reset circuit. The reset switch is used for producing a reset command. The reset circuit is used for producing a reset signal to reset the processing apparatus in accordance with the reset command. The reset switch includes a delay circuit and a switching circuit. The delay circuit delays an input of the reset command to the switching circuit, while the switching circuit produces the reset signal in accordance with the reset command.

An electronic device including a processor and a reset device that resets the processor is also provided. The reset device mainly includes a reset switch and a reset circuit. The reset switch is used for producing a reset command. The reset circuit is used for producing a reset signal to reset the processor in accordance with the reset command. The reset switch includes a delay circuit and a switching circuit. The delay circuit delays an input of the reset command to the switching circuit, while the switching circuit produces the reset signal in accordance with the reset command.

Other advantages and novel features will be drawn from the following detailed description with reference to the attached drawings, in which:

### BRIEF DESCRIPTION OF THE DRAWINGS

FIG. 1 depicts a schematic block diagram of a reset device in accordance with a preferred embodiment of the present invention, the reset device being connected with a MCU;

FIG. 2 depicts a circuit diagram of the reset device of FIG. 1;

FIG. 3A and FIG. 3B are waveform graphs showing voltage variations at several ports of the reset device versus time when a rest switch of the reset device is activated for a period, FIG. 3A showing the voltage variations versus time when the reset switch is activated continuously, and FIG. 3B showing the voltage variation versus time when the reset switch is activated discontinuously; and

FIG. 4 depicts a schematic block diagram of a related art.

### DETAILED DESCRIPTION OF THE PREFERRED EMBODIMENTS

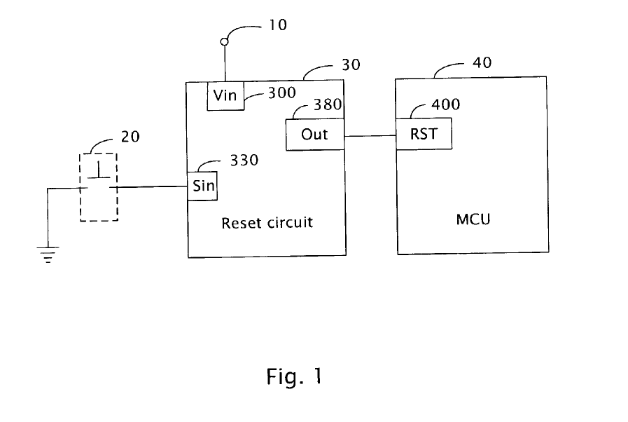

Referring to FIG. 1, a reset device provided in the preferred embodiment mainly includes a reset switch 20 and a reset circuit 30 positioned in series between the ground potential and a processor 40 of an electronic device. In FIG. 1, an exemplary example of the processor is given as a micro controller unit (simplified as MCU) 40. The reset circuit 30 includes an operating voltage input port (Vin) 300, a reset command input port (Sin) 330, and a reset signal output port (Out) 380. The operating voltage input port 300 is connected to a voltage source 10 to receive an operating voltage therefrom for the reset circuit 30. The reset command input port 330 is connected to the reset switch 20. The reset switch 20 is provided to produce reset commands in accordance with a user's; direct or indirect acts thereon. In one embodiment, the reset switch 20 is in a form of self-returning. The user acts on (e.g., press) the self-return switch for a continuous time period, thereby a reset command is produced and outputted to the reset circuit 30 via the reset command input port 330. The reset signal output 380 is connected to a reset port (RST) 400 of the MCU 40. The reset circuit 30 produces a reset signal in accordance with the reset command. The reset signal is sent to trigger a reset of the MCU 40 via the reset signal output port 380 and the reset port 400.

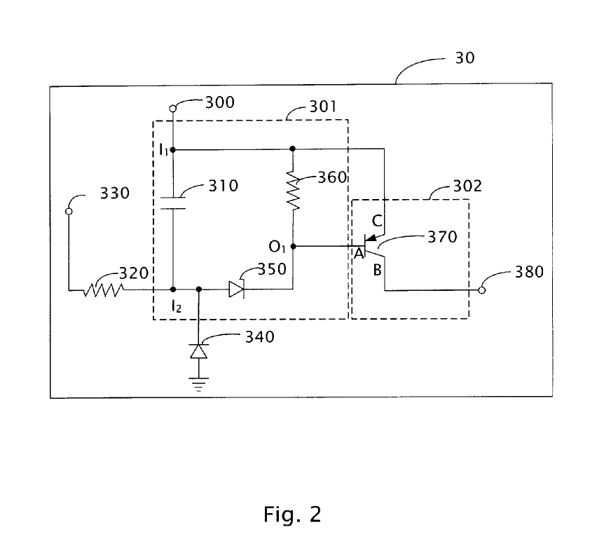

Referring to FIG. 2, the reset circuit 30 further includes a delaying circuit 301 and a switching circuit 302. The delaying circuit 301 is positioned between the reset switch 20 and the switching circuit 302, and delays the input of the reset command to the switching circuit 302. In one embodiment, the delaying circuit is embodied as a Resistance-Capacitance (RC) differentiating circuit constructed with a capacitive element such as a capacitor 310, a voltage stabilizing element such as a voltage stabilizing diode 350, and a resistive element such as a resistor 360. The resistor 360 is connected with the voltage stabilizing diode 350 in series and forms a node O1 with the voltage stabilizing diode 350. The combination of the serially connection of the resistor 360 and the voltage stabilizing diode 350 is further connected with the capacitor 310 in parallel, and forms nodes I1 and I2 with the capacitor 310. The node I1 is formed between the capacitor 310 and the resistor 360, and is connected to the operating voltage input port 300. The node I2 is formed between the capacitor 310 and an anode of the voltage stabilizing diode 350, and is connected to the reset command input port 330 via a resistor 320. The node O1 is connected to the switching circuit 302. The switching circuit 302 has three-terminals, of which a first terminal A is connected to the node O1 and is controllable by the delaying circuit 301, a second terminal B is connected to the reset signal output 380, and a third terminal C is connected to the node I1. The first terminal A receives the reset command from the delaying circuit 301 and controls the switching circuit 302 to close, thereby the second terminal B produces the reset signal. The switching circuit 302 is embodied in one embodiment as a transistor including a base, a collector, and an emitter, each respectively forming the first terminal A, the second terminal, and the third terminal C of the switching circuit 302.

A discharging circuit is constructed by a diode 340 with an anode thereof being connected to a ground potential, and a cathode thereof being connected to the node I2. The discharging circuit serves as a protecting apparatus for other components of the reset circuit 30 when the reset switch 20 is not activated.

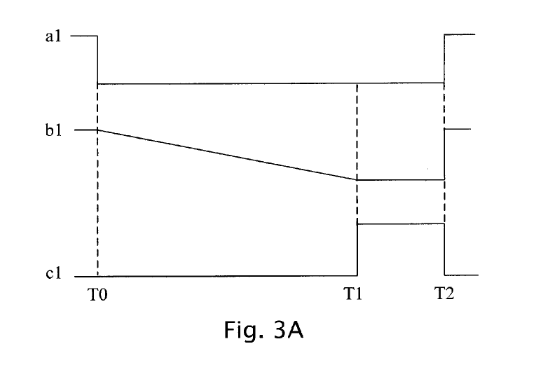

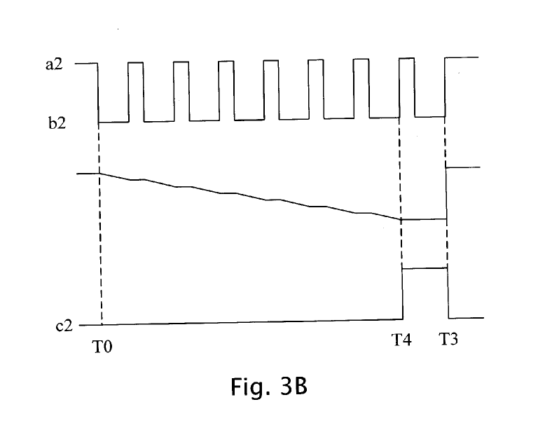

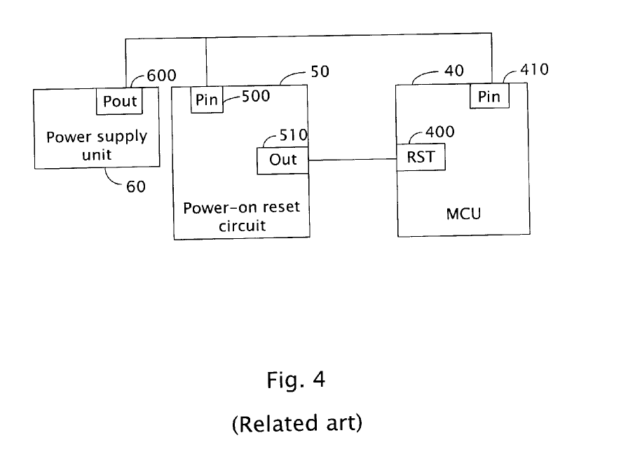

FIG. 3A and FIG. 3B illustrate voltage variations versus time at the reset command input port 330, the node O1, and the reset signal output port 380 when the reset switch 20 is activated over a continuous time period. Lines a1, b1, and c1 each represent voltage variation respectively at the reset command input port 330, the node O1, and the reset signal output port 380 when the reset switch 20 is activated continuously (pressed down) by the user over a time period. Similarly, lines a2, b2 and c2 each represent a voltage variation respectively at the reset command input port 330, the node O1, and the reset signal output port 380, when the reset switch 20 is activated discontinuously (hit on repeatedly) by the user. T0˜T2 and T0˜T3 respectively denote a time duration when the reset switch 20 is activated continuously and discontinuously, while T1 and T4 respectively indicate times at which the reset signal is produced.

The reset switch 20 is activated at T0, and the action lasts to T2 (or T3). The reset command input port 330 is accordingly connected to the ground potential and thus is at a low-level voltage. The delaying circuit 301 functions and gradually changes the node O1 from a high-level voltage to a low-level voltage during T0˜T1 (or T0˜T4). The low-level voltage at the node O1 controls the switching circuit 302 to conduct. The reset signal output port 380 thus changes from a low-level voltage to a high-level voltage at T1 (or T4), and a reset signal is accordingly produced.

The reset switch 20 can be defined with a function button already pre-arranged on the electronic device. For example, regarding a display device, a power button can be adopted to serve as the reset switch 20. A user of the display device can press the power button for a period to reset and re-enable the display device when the display device is not working properly.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A reset device for resetting a processor, comprising:
a reset switch for producing a reset command; and
a reset circuit for producing a reset signal to reset the processor in accordance with the reset command, the reset circuit comprising a delay circuit and a switching circuit;
wherein the delay circuit delays an input of the reset command to the switching circuit, and the switching circuit produces the reset signal in accordance with the reset command.

2. The reset device as claimed in claim 1, wherein the reset circuit further comprises a reset command input port connected to the reset switch, an operating voltage input port connected to a voltage source, and a reset signal output port connected to the processor.

3. The reset device as claimed in claim 2, wherein the delaying circuit is an resistance-capacitance (RC) differentiating circuit with a resistive element and a capacitive element thereof being a parallel connection between the operating voltage input port and the reset command input port.

4. The reset device as claimed in claim 3, wherein the RC differentiating circuit further comprises a voltage stabilizing element with an anode thereof being connected to the reset command input port and a cathode thereof being connected to the operating voltage input port via the resistive element.

5. The reset device as claimed in claim 4, wherein the switching circuit is in a three terminal form, of which a first terminal is connected between the resistive element and the voltage stabilizing element and is controllable by the delay circuit, a second terminal is connected to the reset signal input port, and a third terminal is connected to the operating voltage input port.

6. The reset device as claimed in claim 5, wherein the first terminal of the switching circuit receives the reset command and controls the switching circuit to be closed and controls the second terminal to produce the reset signal.

7. An electronic device comprising:
a processor;
a reset switch for producing a reset command; and
a reset circuit for producing a reset signal to reset the processor in accordance with the reset command, and comprising a delay circuit and a switching circuit;
wherein, the delay circuit delays an input of the reset command to the switching circuit, and the switching circuit produces the reset signal in accordance with the reset command.

8. The electronic device as claimed in claim 7, wherein the reset circuit further comprises a reset command input port connected to the reset switch, an operating voltage input port connected to a voltage source and a reset signal output port connected to the processor.

9. The electronic device as claimed in claim 8, wherein the delaying circuit is an resistance-capacitance (RC) differentiating circuit with a resistive element and a capacitive element thereof being a parallel connection between the operating voltage input port and the reset command input port.

10. The electronic device as claimed in claim 9, wherein the RC differentiating circuit further comprises a voltage stabilizing element with an anode thereof being connected to the reset command input port and a cathode thereof being connected to the operating voltage input port via the resistive element.

11. The electronic device as claimed in claim 10, wherein the switching circuit is in a three terminal form, of which a first terminal is connected between the resistive element and the voltage stabilizing element and is controllable by the delay circuit, a second terminal is connected to the reset signal input port, and a third terminal is connected to the operating voltage input port.

12. The electronic device as claimed in claim 11, wherein the first terminal of the switching circuit receives the reset command and controls the switching circuit to be closed and controls the second terminal to produce the reset signal.
